(19) United States
(12) Patent Application Publication
(10) Pub. No.: US 2014/0319487 A1
(43) Pub. Date: Oct. 30, 2014

(54) DONOR FILM FOR LASER INDUCED THERMAL IMAGING, METHOD OF MANUFACTURING ORGANIC LIGHT-EMITTING DISPLAY APPARATUS USING THE DONOR FILM, AND ORGANIC LIGHT-EMITTING DISPLAY APPARATUS MANUFACTURED BY USING THE DONOR FILM

(71) Applicant: SAMSUNG DISPLAY CO., LTD., Yongin-City (KR)

(72) Inventors: Jin-Woo PARK, Yongin-City (KR); Myung-Jong JUNG, Yongin-City (KR)

(73) Assignee: SAMSUNG DISPLAY CO., LTD., Yongin-City (KR)

(21) Appl. No.: 14/219,095

(22) Filed: Mar. 19, 2014

(30) Foreign Application Priority Data
Apr. 29, 2013 (KR) 10-2013-0047695

(51) Int. Cl. H01L 27/32; H01L 51/56

(52) U.S. Cl. CPC H01L 27/3211; H01L 51/56
USPC 257/40; 438/35

(57) ABSTRACT

Provided is a donor film for laser induced thermal imagining, a method of manufacturing an organic light-emitting display apparatus using the donor film, and an organic light-emitting display apparatus manufactured by using the same. The donor film includes a base film, a light to heat conversion layer on the base film, and a transfer layer on the light to heat conversion layer. The transfer layer includes a first color intermediate layer including a first color host and an emission layer between the first color intermediate layer and the light to heat conversion layer.

### CROSS-REFERENCE TO RELATED APPLICATION

Korean Patent Application No. 10-2013-0047695 filed on Apr. 29, 2013, in the Korean Intellectual Property Office, and entitled: “DONOR FILM FOR LASER INDUCED THERMAL IMAGING, METHOD OF MANUFACTURING ORGANIC LIGHT-EMITTING DISPLAY APPARATUS USING THE DONOR FILM, AND ORGANIC LIGHT-EMITTING DISPLAY APPARATUS MANUFACTURED BY USING THE DONOR FILM,” is incorporated by reference herein in its entirety.

### BACKGROUND

1. Field

Embodiments relate to a donor film for laser induced thermal imaging, a method of manufacturing an organic light-emitting display apparatus using the donor film, and an organic light-emitting display apparatus manufactured by using the donor film.

2. Description of the Related Art

An organic light-emitting display apparatus is a display apparatus including an organic-light emitting diode in a display region, wherein the organic light-emitting diode includes a pixel electrode and a counter electrode that face each other, and an intermediate layer disposed between the pixel and counter electrodes and including an emission layer.

Any one of various methods may be used to form at least a part of the intermediate layer while manufacturing the organic light-emitting display apparatus, such as a deposition method, an inkjet printing method, or laser induced thermal imaging (LITI). However, a general method of manufacturing an organic light-emitting display apparatus includes faults, for example, a process of forming at least a part of an intermediate layer may be complex or a layer may be damaged while being formed.

### SUMMARY

One or more embodiments is directed to providing a donor film for laser induced thermal imaging, the donor film including a base film, a light to heat conversion layer on the base film, and a transfer layer on the light to heat conversion layer. The transfer layer may include a first color intermediate layer including a first color host and an emission layer between the first color intermediate layer and the light to heat conversion layer.

The emission layer may emit light in a wavelength band of a color other than a first color.

The first color host may be a blue host. The emission layer may emit a light in a wavelength band of a second color. The second color may be red or green.

The first color intermediate layer may further include a hole transport material. The first color intermediate layer may further include an electron acceptor.

The transfer layer may further include a hole injection layer between the emission layer and the first color intermediate layer.

One or more embodiments is directed to providing a method of manufacturing an organic light-emitting display apparatus, the method including forming a first pixel electrode and a second pixel electrode, forming a first hole injection layer on the first and second pixel electrodes, forming a first color emission layer on the first hole injection layer to correspond to the first and second pixel electrodes, and forming a second color emission layer and a first color intermediate layer to correspond to the second pixel electrode via laser induced thermal imaging, the first color intermediate layer having a first color host, such that the first color intermediate layer contacts the first color emission layer.

Forming the second color emission layer and the first color intermediate layer may include forming the first color intermediate layer and the second color emission layer together via the laser induced thermal imaging.

Forming the second color emission layer and the first color intermediate layer may include forming the second color emission layer and the first color intermediate layer, the second color emission layer emitting light in a wavelength band of a color other than a first color.

Forming the second color emission layer and the first color intermediate layer may include forming the second color emission layer and the first color intermediate layer, the first color host being a blue host. Forming the second color emission layer and the first color intermediate layer may include forming the second color emission layer and the first color intermediate layer, the second color emission layer emitting light in a wavelength band of red or green.

Forming the second color emission layer and the first color intermediate layer may include forming the second color emission layer and the first color intermediate layer, the first color intermediate layer having a hole transport material and the first color host. Forming the second color emission layer and the first color intermediate layer may include forming the second color emission layer and the first color intermediate layer, first color intermediate layer having a hole transport material and an electron acceptor.

Forming the second color emission layer and the first color intermediate layer may include forming the second emission layer, the first color host, and a second hole injection layer interposed between the second color emission layer and the first color host via laser induced thermal imaging.

One or more embodiments is directed to providing an organic light-emitting display apparatus including: a first pixel electrode and a second pixel electrode; a first hole injection layer disposed on the first and second pixel electrodes; a first color emission layer disposed on the first hole injection layer to correspond to the first and second pixel electrodes; a first color intermediate layer disposed on the first color emission layer to correspond to the second pixel electrode, and having a first color host; and a second color emission layer disposed on the first color intermediate layer to correspond to the second pixel electrode.

The second color emission layer may be configured to emit a light in a wavelength band of a color other than a first color.

The first color host may be a blue host. The second color emission layer may be configured to emit a light in a wavelength band of red or green.

The first color intermediate layer may further include a hole transport material. The first color intermediate layer may further include an electron acceptor.

The first color intermediate layer and the second color emission layer may be patterned in a same shape.

The transfer layer may further include a second hole injection layer interposed between the second color emission layer and the first color intermediate layer. The first color intermediate layer, the second hole injection layer, and the second color emission layer may be patterned in a same shape.

### BRIEF DESCRIPTION OF THE DRAWINGS

Features will become apparent to those of skill in the art by describing in detail exemplary embodiments with reference to the attached drawings in which:

FIGS. 1 through 6 illustrate cross-sectional views for describing stages in a method of manufacturing an organic light-emitting display apparatus according to an embodiment;

FIG. 7 illustrates a cross-sectional view of an organic light-emitting display apparatus according to an embodiment; and

FIG. 8 illustrates a cross-sectional view of an organic light-emitting display apparatus according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Also, meanings of an x-axis, a y-axis, and a z-axis are not limited to three axes on an orthogonal coordinates system, but may be wider. For example, the x-, y-, and z-axes may cross each other at right angles, but may alternatively denote other directions that do not cross each other at right angles.

As used herein, the term “and/or” includes any and all combinations of one or more of the associated listed items. Expressions such as “at least one of,” when preceding a list of elements, modify the entire list of elements and do not modify the individual elements of the list.

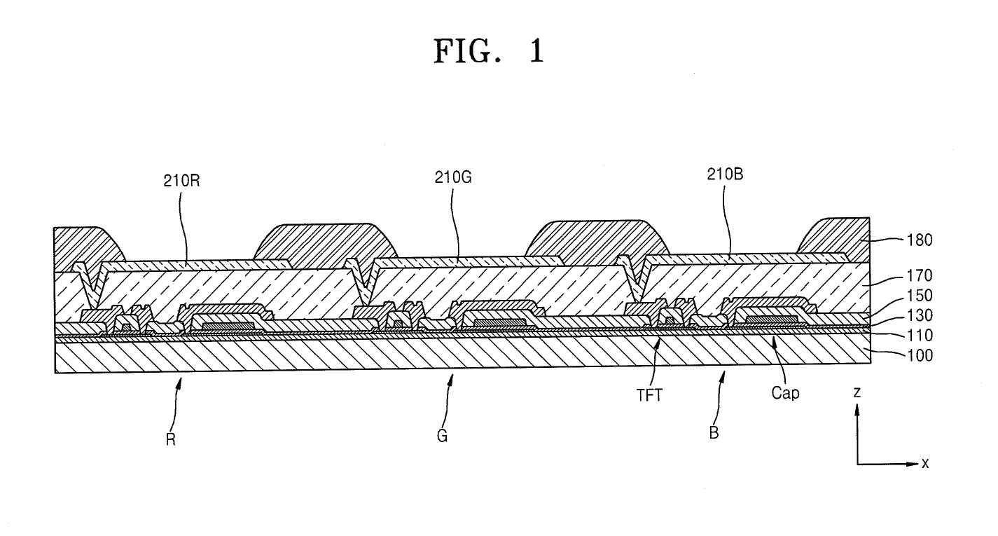

FIGS. 1 through 6 illustrate cross-sectional views for describing stages in a method of manufacturing an organic light-emitting display apparatus, according to an embodiment.

First, as shown in FIG. 1, a backplane is prepared. Here, the backplane may at least include a substrate 100, pixel electrodes 210R, 210G, and 210B formed on the substrate 100, and a pixel-defining film 180 exposing at least parts of the pixel electrodes 210R, 210G, and 210B, including center portions thereof. Here, based on the substrate 100, the pixel-defining film 180 may protrude in a +z direction further than the pixel electrodes 210R, 210G, and 210B.

The pixel electrode 210B from among the pixel electrodes 210R, 210G, and 210B may be a first pixel electrode, and at least one of the pixel electrodes 210R and 210G may be a second pixel electrode, because as will be described later, an intermediate layer formed on the first pixel electrode and an intermediate layer formed on the second pixel electrode may be different from each other. Hereinafter, for convenience of description, the terms pixel electrodes 210R, 210G, and 210B are used instead of the terms first and second pixel electrodes.

The pixel electrodes 210R, 210G, and 210B may be (semi-)transparent electrodes or reflective electrodes. When the pixel electrodes 210R, 210G, and 210B are (semi-)transparent electrodes, they may be formed of indium tin oxide (ITO), indium zinc oxide (IZO), zinc oxide (ZnO), indium oxide (In₂O₃), indium gallium oxide (IGO), aluminum zinc oxide (AZO), and so forth. When the pixel electrodes 210R, 210G, and 210B are reflective electrodes, they may include a reflective film formed of silver (Ag), magnesium (Ag), aluminum (Al), platinum (Pd), gold (Au), nickel (Ni), neodymium (Nd), iridium (Ir), chromium (Cr), or a compound thereof, and a film formed of ITO, IZO, ZnO, or In₂O₃. However, structures and materials of the pixel electrodes 210R, 210G, and 210B are not limited thereto, and may vary accordingly.

The pixel-defining film 180 may define a pixel by having an opening corresponding to each sub-pixel, i.e., an opening exposing the center portions of the pixel electrodes 210R, 210G, and 210B, or all of the pixel electrodes 210R, 210G, and 210B. The pixel-defining film 180 may prevent an arc from being generated at ends of the pixel electrodes 210R, 210G, and 210B by increasing distances between the ends of the pixel electrodes 210R, 210G, and 210B and a counter electrode (not shown) at tops of the pixel electrodes 210R, 210G, and 210B.

The backplane may further include other components if required. For example, as shown in FIG. 1, a thin-film transistor TFT or a capacitor Cap may be formed on the substrate 100. Also, the backplane may further include other components, e.g., a buffer layer 110 for preventing impurities from penetrating into a semiconductor layer of the thin-film transistor TFT, a gate insulation film 130 for insulating the semiconductor layer of the thin-film transistor TFT and a gate electrode, an interlayer insulation film 150 for insulating source and drain electrodes of the thin-film transistor TFT and the gate electrode, a planarization film 170 covering the thin-film transistor TFT and having an approximately flat top surface, and so forth.

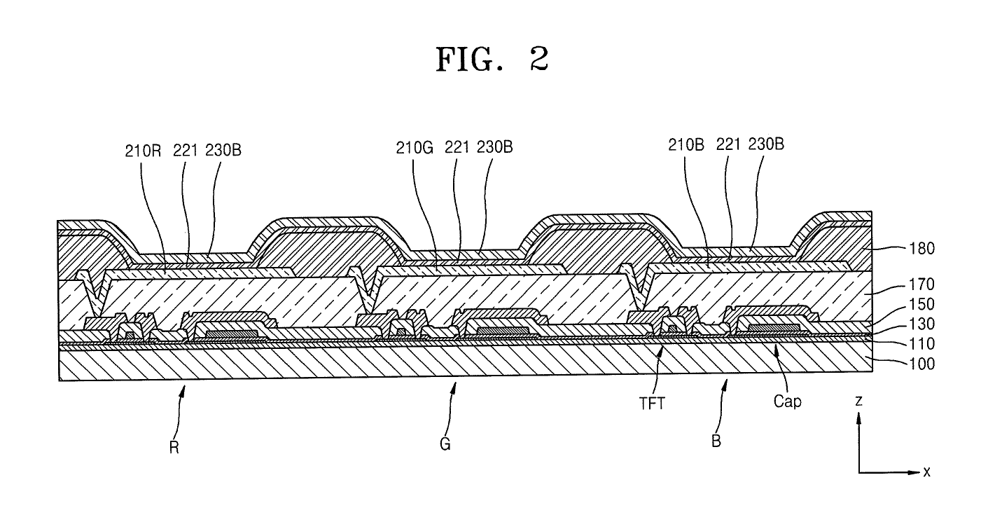

After preparing the backplane as such, a first hole injection layer 221 and a first color emission layer 230B may be formed as shown in FIG. 2. In detail, the first hole injection layer 221 is formed on the pixel electrodes 210R, 210G, and 210B via a deposition method, e.g., a chemical vapor deposition (CVD) method, or a screen printing method. The first color emission layer 230B may also be formed on the first hole injection layer 221 to correspond to the pixel electrodes 210R, 210G, and 210B via a deposition method, e.g., a CVD method, or a screen printing method. In other words, the first hole injection layer 221 and the first color emission layer 230B are formed to approximately correspond to an entire surface of the substrate 100. The first hole injection layer 221 and the first color emission layer 230B may be formed by using a low molecular material, e.g., copper phthalocyanine (CuPc) or tris-8-hydroxyquinoline aluminum (Alq3), or a high molecular material, e.g., a poly-phenylenevinylene (PPV)-based material or a polyfluorene-based material.

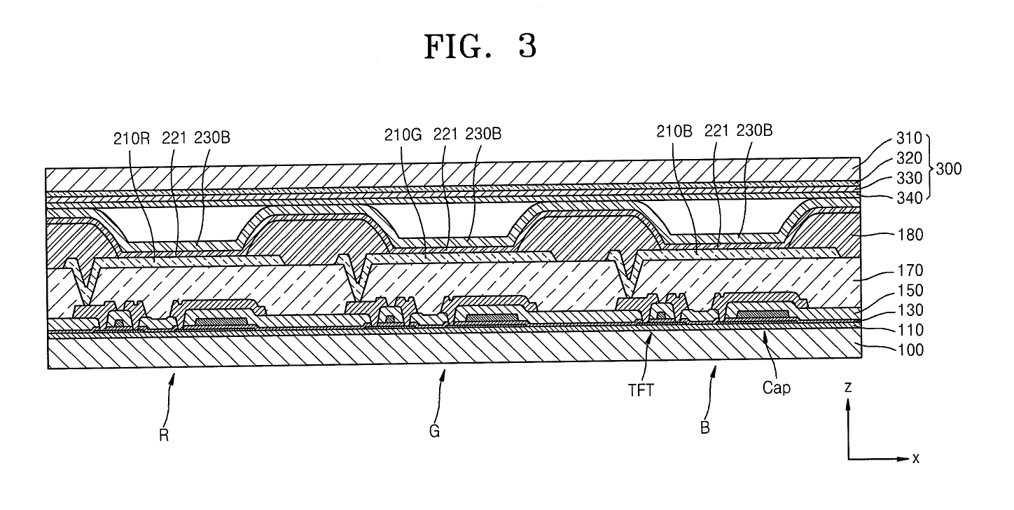

Then, as shown in FIG. 3, a donor film 300 for laser induced thermal imaging is disposed on the backplane. Before disposing the donor film 300 on the backplane, one or more required layers may be formed on the pixel electrodes 210R, 210G, and 210B, or on the entire surface of the substrate 100.

The donor film 300 may include a base film 310, a light to heat conversion layer 320, a first transfer layer 330, and a second transfer layer 340.

The base film 310 may be formed of polyacryl, polyepoxy, polyethylene, polystyrene, and/or polyester, e.g., polyethylene terephthalate (PET), in order to transfer a light to the light to heat conversion layer 320.

The light to heat conversion layer 320 is a layer for converting at least a part of energy of a laser beam to heat by absorbing the laser beam. The light to heat conversion layer 320 may be a metal film formed of a metal, e.g., aluminum or silver, capable of absorbing a light in an infrared light-visible light region, an oxide/sulfide film of such a metal, or an organic polymer film including carbon black or graphite.

The first and second transfer layers 330 and 340 are layers transferred on a contacting surface by heat generated by the light to heat conversion layer 320. The first transfer layer 330 may include a second color emission layer material and the second transfer layer 340 may include a first color host material. The first transfer layer 330 is disposed relatively close to the light to heat conversion layer 320 with respect to the second transfer layer 340. Here, if required, one or more transfer layers other than the first and second transfer layers 330 and 340 may be added.

An intermediate layer (not shown) may be interposed between the first and second transfer layers 330 and 340 and the light to heat conversion layer 320. The intermediate layer may be a gas generating layer for generating a nitrogen gas or a hydrogen gas by absorbing light or heat transferred from the light to heat conversion layer 320 to generate a decomposition reaction by being formed of pentaerythritol tetranitrate (PETN) or trinitrotoluene (TNT), or a preventing layer for preventing a part of the light to heat conversion layer 320 from being smeared on the first transfer layer 330 while transferring the first and second transfer layers 330 and 340. According to the gas generating layer, a gas may be generated so that the first and second transfer layers 330 and 340 are satisfactorily separated from the intermediate layer or the light to heat conversion layer 320 while being transferred.

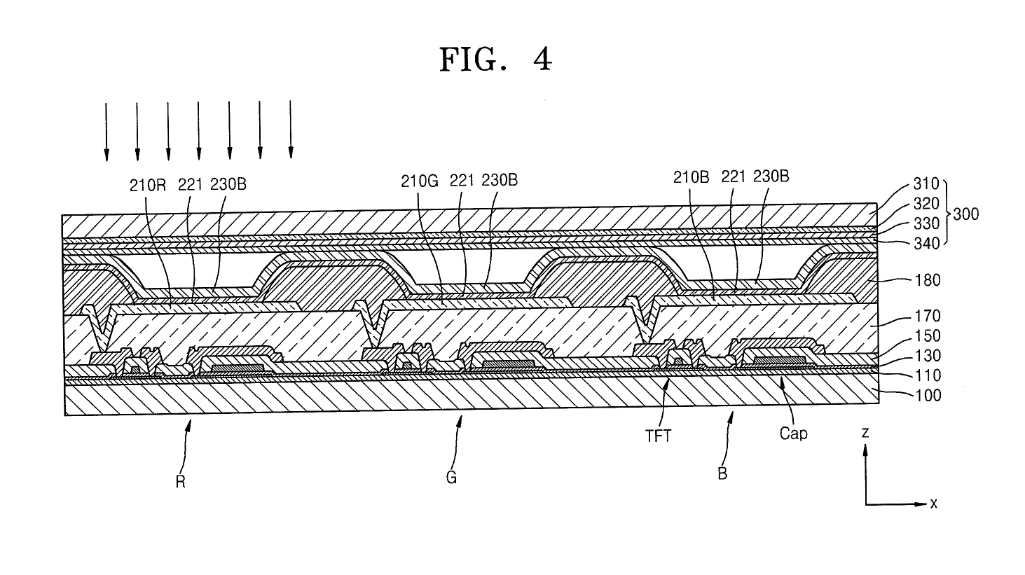

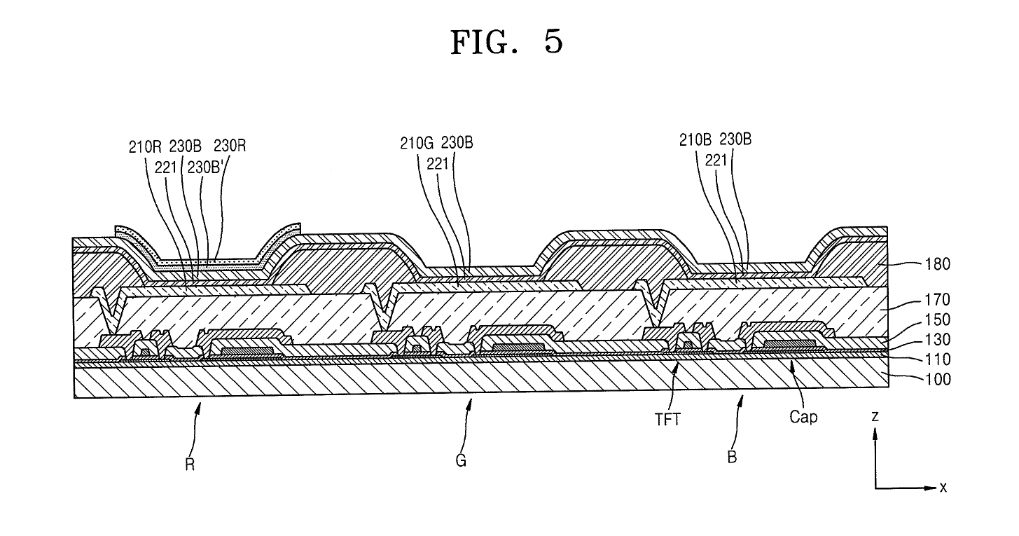

Then, as shown in FIG. 4, a laser beam is irradiated on a predetermined portion of the donor film 300 so that parts of the first and second transfer layers 330 and 340 of the donor film 300 are transferred to the backplane as shown in FIG. 5. In FIG. 5, the second transfer layer 340 is transferred on the pixel electrode 210R to become a first color intermediate layer 230B′, and the first transfer layer 330 is transferred on the pixel electrode 210R accordingly to become a second color emission layer 230R disposed on the first color intermediate layer 230B′.

A transfer process will now be simply described. For example, as shown in FIG. 4, when the second transfer layer 340 of the donor film 300 includes a second color emission layer material, the laser beam is irradiated on a portion of the donor film 300, which corresponds to a sub-pixel of a second color from among a red sub-pixel R, a green sub-pixel G, and a blue sub-pixel B of the backplane. In FIG. 4, the second color is red. In this case, when heat is generated in a region of the light to heat conversion layer 320 where the laser beam is irradiated, the base film 310 in the region where the laser beam is irradiated is expanded by the heat, and thus the first and second transfer layers 330 and 340 in the region where the laser beam is irradiated contact a portion on the pixel electrode 210R of the backplane of the first color emission layer 230B. Here, the light to heat conversion layer 320 or the intermediate layer may also be expanded.

Since the first and second transfer layers 330 and 340 in the region where the laser beam is irradiated contact the portion on the pixel electrode 210R of the backplane of the first color emission layer 230B and are affected by the heat generated by the light to heat conversion layer 320, the first and second transfer layers 330 and 340 in the region where the laser beam is irradiated are transferred to the portion on the pixel electrode 210R of the backplane of the first color emission layer 230B. However, since the first and second transfer layers 330 and 340 in a region where the laser beam is not irradiated are not affected by the heat even if they partially contact another portion of the first color emission layer 230B, the first and second transfer layers 330 and 340 in the region where the laser beam is not irradiated may not be transferred although smeared on the first color emission layer 230B.

Then, when the donor film 300 is detached from the backplane, the first color intermediate layer 230B′ and the second color emission layer 230R are sequentially stacked on the portion on the pixel electrode 210R of the backplane of the first color emission layer 230B as shown in FIG. 5. As such, the first color intermediate layer 230B′ and the second color emission layer 230R are formed together via the laser induced thermal imaging. Here, the second color emission layer 230R may emit a light in a wavelength band of a color other than a first color emitted by the first color emission layer 230B. For example, the first color emission layer 230B may emit blue light and the second color emission layer 230R may emit red light. Here, the second transfer layer 340 of the donor film 300 may include a blue host such that the first color intermediate layer 230B′ may include a blue host.

Alternatively, only the first transfer layer 330 may exist and the first transfer layer 330 may be transferred on the first color emission layer 230B to become the second color emission layer 230R, without using the second transfer layer 340 that becomes the first color intermediate layer 230B′. However, in this case, the second color emission layer 230R may not be properly formed, and may be detached or damaged.

According to the method of the current embodiment, while performing the laser induced thermal imaging, the second transfer layer 340 in the region where the laser beam is irradiated contacts and is irradiated to the portion on the pixel electrode 210R of the backplane of the first color emission layer 230B. Here, a sufficient bonding force needs to be obtained between the second transfer layer 340 and the first color emission layer 230B so that the second transfer layer 340 remains on the first color emission layer 230B while detaching the donor film 300. If the sufficient bonding force is not obtained between the second transfer layer 340 and the first color emission layer 230B, a transfer defect may be generated, for example, the second transfer layer 340 may not remain on but may be detached from the first color emission layer 230B even if it contacts the first color emission layer 230B while detaching the donor film 300.

However, according to the method of the current embodiment, the second transfer layer 340 includes the first color host. Accordingly, properties of the second transfer layer 340 may be quite similar to those of the first color emission layer 230B, and thus when the second transfer layer 340 and the first color emission layer 230B contact each other, the bonding force is increased. As a result, when the donor film 300 is detached, the portion of the second transfer layer 340 contacting the first color emission layer 230B is not detached or damaged, and may remain on the first color emission layer 230B.

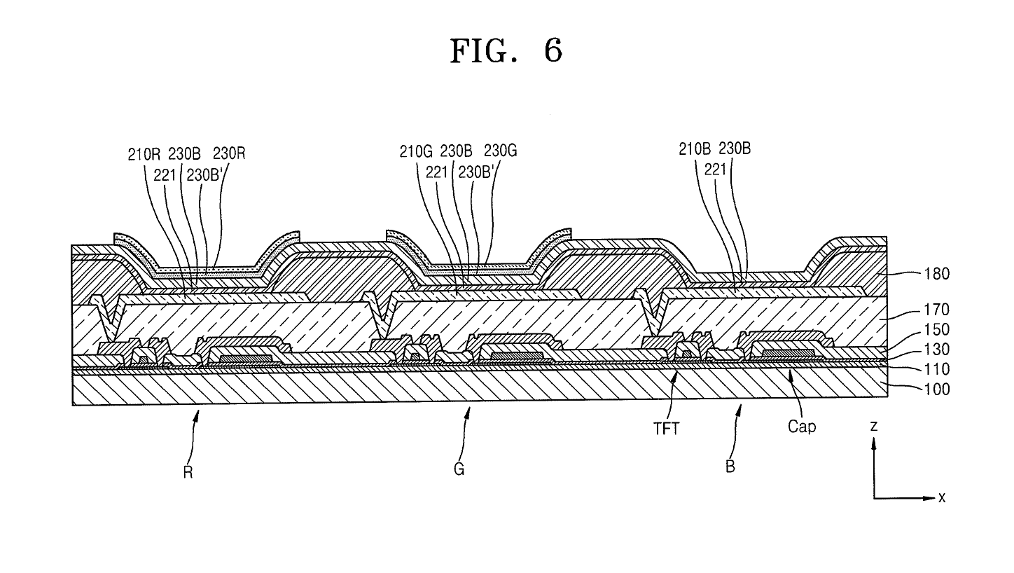

Then, similarly, the first color intermediate layer 230B′ including the first color host and an emission layer 230G may be formed on the pixel electrode 210G via the laser induced thermal imaging as shown in FIG. 6. In this case as well, a defect rate may be remarkably reduced while transferring the first color intermediate layer 230B′ and the emission layer 230G by contacting the first color intermediate layer 230B′ to the first color emission layer 230B having similar properties. As described above, for example, when the first color emission layer 230B emits a light in a wavelength band of blue and the second color emission layer 230R emits a light in a wavelength band of red, the emission layer 230G may emit a light in a wavelength band of green.

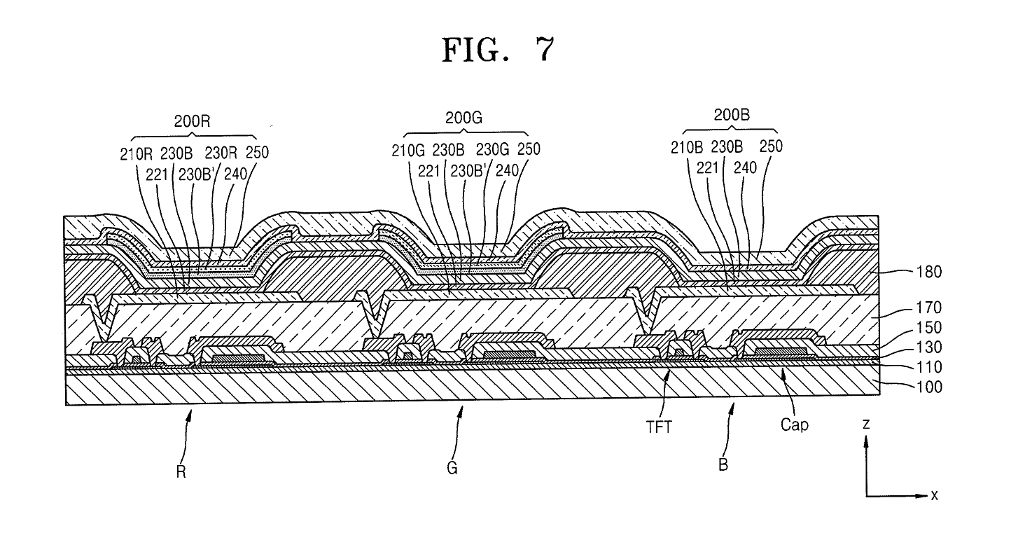

Then, an electron injection layer 240 and a counter electrode 250 may be formed on the entire surface of the substrate 100 or to correspond to most of the entire surface of the substrate 100 by using a deposition method, e.g., a CVD method, to manufacture an organic light-emitting display apparatus shown in FIG. 7. The electron injection layer 240 may be formed of Alq3. The counter electrode 250 contacts an electrode power supply line outside a display region to receive an electric signal from the electrode power supply line. The counter electrode 250 may be a (semi-)transparent electrode or a reflective electrode. When the counter electrode 250 is a (semi-) transparent electrode, the counter electrode 250 may include a film of Li, Ca, LiF/Ca, LiF/Al, Al, Mg, or a compound thereof, and an auxiliary electrode or bus electrode line formed of a (semi-)transparent material, e.g., ITO, IZO, ZnO, or In₂O₃. When the counter electrode 250 is a reflective electrode, the counter electrode 250 may include a layer including one or more materials from among Li, Ca, LiF/Ca, LiF/Al, Al, Ag, and Mg. However, structures and materials of the counter electrode 350 are not limited thereto, and may vary accordingly.

According to the method described above, while transferring the second color emission layer 230R or the emission layer 230G on the first color emission layer 230B via the laser induced thermal imaging, the first color intermediate layer 230B′ including the first color host is also transferred, and thus a transfer defect may be effectively prevented according to a sufficient bonding force between the first color intermediate layer 230B′ and the first color emission layer 230B having similar properties.

Also, according to the method of the current embodiment, the first color emission layer 230B is formed on the entire or most surface of the substrate 100, and the laser induced thermal imaging is performed only on two types of the red, green, and blue sub-pixels R, G, and B. Accordingly, manufacture processes may be simplified and manufacture times may be remarkably reduced compared to when the laser induced thermal imaging is performed on all three types of the red, green, and blue sub-pixels R, G, and B.

Meanwhile, since a blue host basically has a high band gap, the blue host may considerably interfere with hole transportation, and thus a bulk resistance of the organic light-emitting display apparatus may be increased, thereby deteriorating characteristics, e.g., increasing a driving voltage. Accordingly, the second transfer layer 340 of the donor film 300 may further include a hole transport material, as well as the first color host.

Here, the first color intermediate layer 230B′ on the pixel electrode 210R, which is formed as the second transfer layer 340 is transferred, has the first color host, thus increasing the bonding force with the first color intermediate layer 230B′. Moreover, mobility of holes is increased by including the hole transport material in the second transfer layer 340. Accordingly, despite of the existence of the first color host, characteristics of the organic light-emitting display apparatus may be effectively prevented from being deteriorated. Examples of the hole transport material include poly-(3,4)-ethylene-dihydroxy thiophene (PEDOT), polyaniline (PANI), doped or undoped polythiophene, or a p-doped material.

Alternatively, the second transfer layer 340 of the donor film 300 may include an electron acceptor instead of the hole transport material. Here, the first color intermediate layer 230B′ on the pixel electrode 210R, which is formed as the second transfer layer 340 is transferred, may have an improved bonding force with the first color intermediate layer 230B′ by including the first color host and may also have high mobility of holes by including the electron acceptor. Thus, the characteristics of the organic light-emitting display apparatus may be effectively prevented from being deteriorated despite of the existence of the first color host. The electron acceptor may be formed of C₆₀, 1,4,5,8,9,11-hexaazatriphenylene-hexacarbonitrile (HAT-CN), or 2-(7-dicyanomethylene-1,3,4,5,6,8,9,10-octafluoro-7H-pyrene-2-ylidene)-malononitrile (NDP-9).

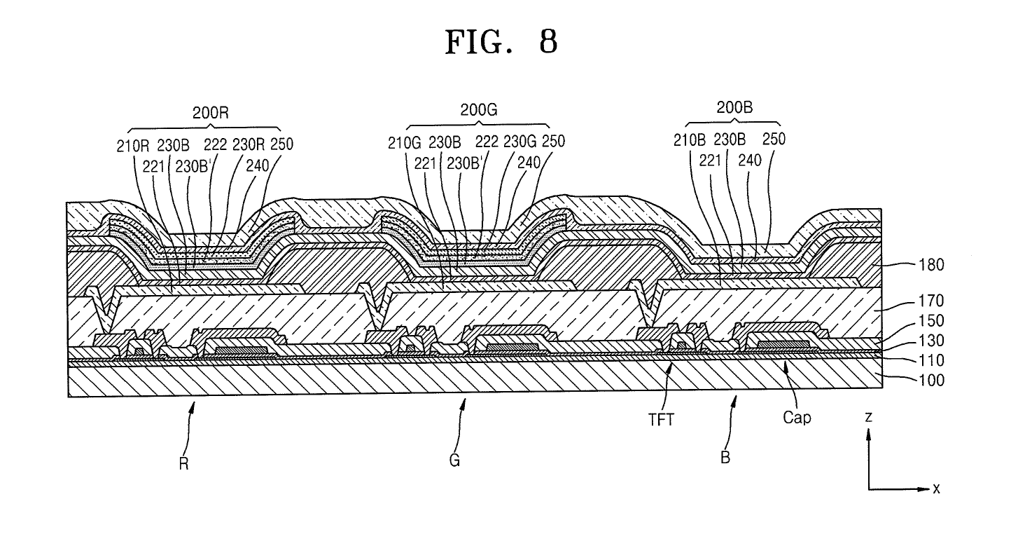

Moreover, on the pixel electrode 210R, the second color emission layer 230R may mainly emit light different than the first color emission layer 230B. Accordingly, a third transfer layer having a hole injection material may be interposed between the first and second transfer layers 330 and 340 of the donor film 300, such that the first color intermediate layer 230B′, a second hole injection layer 222, and the second color emission layer 230R are sequentially stacked on the pixel electrode 210R from the first color emission layer 230B as shown in FIG. 8, via the laser induced thermal imaging. Here, the first color intermediate layer 230B′, the second hole injection layer 222, and the emission layer 230G may also be sequentially stacked on the pixel electrode 210G from the first color emission layer 230B. The third transfer layer of the donor film 300 for forming the second hole injection layer 222 may include CuPc.

The method of manufacturing an organic light-emitting display apparatus has been mainly described hereinabove, embodiments are not limited thereto. For example, the donor film 300 used in the method is also within the scope of the disclosure.

The donor film 300 according to an embodiment may have a structure shown in FIG. 3. In other words, the donor film 300 may include the base film 310, the light to heat conversion layer 320, the first transfer layer 330, and the second transfer layer 340. Here, the first transfer layer 330 from among the first and second transfer layers 330 and 340 is relatively close to the light to heat conversion layer 320, and may be understood as an emission layer. The second transfer layer 340 is disposed in a direction farther from the light to heat conversion layer 320 based on the first transfer layer 330, and may be understood as a first color intermediate layer including a first color host.

The base film 310 may be formed of polyacryl, polyepoxy, polyethylene, polystyrene, and/or polyester such as PET, in order to transfer a light to the light to heat conversion layer 320.

The light to heat conversion layer 320 is a layer for converting at least a part of energy of a laser beam to heat by absorbing the laser beam. The light to heat conversion layer 320 may be a metal film formed of a metal such as aluminum or silver capable of absorbing a light in an infrared light-visible light region, an oxide/sulfide film of such a metal, or an organic polymer film including carbon black or graphite.

The first and second transfer layers 330 and 340 are layers transferred on a contacting surface by heat generated by the light to heat conversion layer 320. The first transfer layer 330 may include a second color emission layer material and the second transfer layer 340 may include a first color host material. The first transfer layer 330 is disposed relatively close to the light to heat conversion layer 320 with respect to the second transfer layer 340. Here, if required, one or more transfer layers other than the first and second transfer layers 330 and 340 may be added.

The first transfer layer 330 may include a material capable of emitting a light in a wavelength band of a color other than the first color. For example, the first color may be blue, and the second transfer layer 340 may have a blue host while the first transfer layer 330 may include a material capable of emitting a light in a wavelength band of red or blue.

Meanwhile, the second transfer layer 340 may further include a hole transport material or an electron acceptor as well as the first color host, so that mobility of holes is not significantly decreased despite of the existence of the first color host.

Also, the donor film 300 may further include a layer having a hole injection material between the first and second transfer layers 330 and 340 so that a first color intermediate layer having a first color host, a hole injection layer, and an emission layer in a color other than a first color are simultaneously formed during laser induced thermal imaging.

An intermediate layer (not shown) may be interposed between the first and second transfer layers 330 and 340 and the light to heat conversion layer 320. The intermediate layer may be a gas generating layer for generating a nitrogen gas or a hydrogen gas by absorbing light or heat transferred from the light to heat conversion layer 320 to generate a decomposition reaction by being formed of PETN or TNT, or a preventing layer for preventing a part of the light to heat conversion layer 320 from being smeared on the first transfer layer 330 while transferring the first and second transfer layers 330 and 340. According to the gas generating layer, a gas may be generated so that the first and second transfer layers 330 and 340 are satisfactorily separated from the intermediate layer or the light to heat conversion layer 320 while being transferred.

As well as the components described above, the organic light-emitting display apparatus according to the current embodiment may further include the electron injection layer 240 if required, and may also include the counter electrode 250 corresponding to and integrally formed with the pixel electrodes 210R, 210G, and 210B.

When such a donor film 300 according to the current embodiment is used, since the second transfer layer 340 having similar properties as the first color emission layer 230B that is pre-formed contacts the first color emission layer 230B, the second transfer layer 340 and other transfer layers may be formed on the first color emission layer 230B without being detached or damaged while detaching the donor film 300.

Meanwhile, the organic light-emitting display apparatus manufactured as such is also within the scope of the present disclosure.

The organic light-emitting display apparatus according to an embodiment may have a structure shown in FIG. 7. The organic light-emitting display apparatus may basically include the pixel electrode 210B corresponding to the blue sub-pixel B, the pixel electrode 210R corresponding to the red sub-pixel R, and the pixel electrode 210G corresponding to the green sub-pixel G. Also, the organic light-emitting display apparatus may include the first hole injection layer 221 that is disposed on the pixel electrodes 210R, 210G, and 210B without being patterned, and the first color emission layer 230B on the first hole injection layer 221.

The first color intermediate layer 230B′ disposed on the first color emission layer 230B to correspond to the pixel electrode 210R and including the first color host, and the second color emission layer 230R disposed on the first color intermediate layer 230B′ may be disposed on the pixel electrode 210R. Also, the first color intermediate layer 230B′ disposed on the first color emission layer 230B to correspond to the pixel electrode 210G and including the first color host, and the emission layer 230G disposed on the first color intermediate layer 230B′ may be disposed on the pixel electrode 210G. The first color intermediate layer 230B′ and the second color emission layer 23OR may be simultaneously formed via the laser induced thermal imaging, and the first color intermediate layer 230B′ and the emission layer 230G may be simultaneously formed in the same manner. Since the first color intermediate layer 230B′ and the second color emission layer 230R are simultaneously formed via the laser induced thermal imaging, patterning shapes thereof may be the same, for example edges thereof may be matched.

According to the organic light-emitting display apparatus of the current embodiment, since properties of the first color emission layer 230B and properties of the first color intermediate layer 230B′ including the first color host are similar, the bonding force therebetween is sufficient. Accordingly, detachment or damages may be reduced while forming the first color intermediate layer 230B′ and the second color emission layer 230R thereon on the first color emission layer 230B.

The first color emission layer 230B may emit a light in a wavelength band of blue, and the second color emission layer 230R may emit a light in a wavelength band of a color other than the first color, i.e., a light in a wavelength band of red. The emission layer 230G may emit a light in a wavelength band in a color other than the first color, i.e., a light in a wavelength band of green. Here, the first color host of the first color intermediate layer 230B′ may be a blue host.

FIG. 7 is a cross-sectional view of an organic light-emitting display apparatus according to an embodiment.

According to the organic light-emitting display apparatus of FIG. 7, the first color intermediate layer 230B′ may further include a hole transport material or an electron acceptor, and thus mobility of holes is not remarkably reduced despite the existence of the first color host, thereby effectively preventing a driving voltage of the organic light-emitting display apparatus from being increased.

FIG. 8 is a cross-sectional view of an organic light-emitting display apparatus according to another embodiment.

As shown in FIG. 8, the second color emission layer 230R may effectively emit a light by disposing the second hole injection layer 222 between the first color intermediate layer 230B′ and the second color emission layer 230R. Since the first color intermediate layer 230B′, the second hole injection layer 222, and the second color emission layer 230R are simultaneously formed via the laser induced thermal imaging, patterning shapes thereof may be the same, for example, edges thereof may be matched. Here, the second hole injection layer 222 may also be interposed between the first color intermediate layer 230B′ and the emission layer 230G.

According to one or more embodiments, a donor film for laser induced thermal imaging, which is capable of reducing a defect rate while forming an intermediate layer including an emission layer, a method of manufacturing an organic light-emitting display apparatus using the donor film, and an organic light-emitting display apparatus manufactured by using the donor film may be realized. However, embodiments are not limited by such effects.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing an organic light-emitting display apparatus, the method comprising:
forming a first pixel electrode and a second pixel electrode;
depositing a first hole injection layer on the first and second pixel electrodes;
depositing a first color emission layer on the first hole injection layer to correspond to the first and second pixel electrodes; and
forming a second color emission layer and a first color intermediate layer to correspond to the second pixel electrode via laser induced thermal imaging, the first color intermediate layer having a first color host, such that the first color intermediate layer contacts the first color emission layer.

2. The method as claimed in claim 1, wherein forming the second color emission layer and the first color intermediate layer comprises forming the first color intermediate layer and the second color emission layer together via the laser induced thermal imaging.

3. The method as claimed in claim 1, wherein forming the second color emission layer and the first color intermediate layer comprises forming the second color emission layer and the first color intermediate layer, the second color emission layer being capable of emitting a light in a wavelength band of a color other than a first color.

4. The method as claimed in claim 1, wherein forming the second color emission layer and the first color intermediate layer comprises forming the second color emission layer and the first color intermediate layer, the first color host being a blue host.

5. The method as claimed in claim 4, wherein forming the second color emission layer and the first color intermediate layer comprises forming the second color emission layer and the first color intermediate layer, the second color emission layer being capable of emitting a light in a wavelength band of red or green.

6. The method as claimed in claim 1, wherein forming the second color emission layer and the first color intermediate layer comprises forming the second color emission layer and the first color intermediate layer, the first color intermediate layer having a hole transport material and the first color host.

7. The method as claimed in claim 1, wherein forming the second color emission layer and the first color intermediate layer comprises forming the second color emission layer and the first color intermediate layer, first color intermediate layer having a hole transport material and an electron acceptor.

8. The method as claimed in claim 1, wherein forming the second color emission layer and the first color intermediate layer comprises forming the second emission layer, the first color host, and a second hole injection layer interposed between the second color emission layer and the first color host via laser induced thermal imaging.

9. An organic light-emitting display apparatus, comprising:
a first pixel electrode and a second pixel electrode;
a first hole injection layer on the first and second pixel electrodes;
a first color emission layer on the first hole injection layer to correspond to the first and second pixel electrodes;
a first color intermediate layer on the first color emission layer to correspond to the second pixel electrode, and having a first color host; and
a second color emission layer on the first color intermediate layer to correspond to the second pixel electrode.

10. The organic light-emitting display apparatus as claimed in claim 9, wherein the second color emission layer emits light in a wavelength band of a second color different than a first color.

11. The organic light-emitting display apparatus as claimed in claim 9, wherein the first color host is a blue host.

12. The organic light-emitting display apparatus as claimed in claim 11, wherein the second color emission layer emits light in a wavelength band of red or green.

13. The organic light-emitting display apparatus as claimed in claim 9, wherein the first color intermediate layer further comprises a hole transport material.

14. The organic light-emitting display apparatus as claimed in claim 9, wherein the first color intermediate layer further comprises an electron acceptor.

15. The organic light-emitting display apparatus as claimed in claim 9, wherein the first color intermediate layer and the second color emission layer are patterned in a same shape.

16. The organic light-emitting display apparatus as claimed in claim 9, wherein the transfer layer further comprises a second hole injection layer between the second color emission layer and the first color intermediate layer.

17. The organic light-emitting display apparatus as claimed in claim 16, wherein the first color intermediate layer, the second hole injection layer, and the second color emission layer are patterned in a same shape.
